(19) United States
(12) Patent Application Publication
(10) Pub. No.: US 2025/0234564 A1
(43) Pub. Date: Jul. 17, 2025

(54) MULTI-DIE LAYER MEMORY DEVICE

(71) Applicant: Rambus Inc., San Jose, CA (US)

(72) Inventor: Thomas VOGELSANG, Jericho, VT (US)

(21) Appl. No.: 19/009,127

(22) Filed: Jan. 3, 2025

Related U.S. Application Data
(60) Provisional application No. 63/620,945, filed on Jan. 15, 2024.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1436

(57) ABSTRACT

A memory device (e.g., a dynamic random access memory—DRAM) is constructed by stacking, bonding, and processing multiple wafers before separating the devices into individual layered-die assemblies/stacks. A first wafer used to make layered-die assemblies may be fabricated with die having storage capacitors and access transistors. The first wafer is bonded with a second wafer to provide a two wafer layer assembly. The assembly of the first and second wafer layers is processed to fabricate sense amplifiers, wordline driver circuits, and interconnections—including between dies on different wafer layers. A third wafer having the memory device's remaining circuitry is bonded to the assembly using a process that interconnects the die of the third wafer to corresponding die on the other wafer layers.

### BRIEF DESCRIPTION OF THE DRAWINGS

FIGS. 1A-1D are diagrams illustrating a first example layering of a memory device assembly.

FIGS. 2A-2D are diagrams illustrating a second example layering of a memory device assembly.

FIG. 3 illustrates a layered-die memory device assembly.

FIG. 4 is a flowchart illustrating a first example method of assembling a layered-die memory device.

FIG. 5 is a flowchart illustrating a second example method of assembling a layered-die memory device.

FIG. 6 is a flowchart illustrating a third example method of assembling a layered-die memory device.

FIG. 7 is a block diagram illustrating a processing system.

### DETAILED DESCRIPTION OF THE EMBODIMENTS

In an embodiment, a memory device (e.g., a dynamic random access memory—DRAM) is constructed by stacking, bonding, and processing multiple wafers before separating the devices into individual layered-die assemblies/stacks. A first wafer used to make layered-die assemblies may be fabricated with die having storage capacitors and access transistors. The first wafer is bonded with a second wafer to provide a two wafer layer assembly. The assembly of the first and second wafer layers is processed to fabricate sense amplifiers, wordline driver circuits, and interconnections—including between dies on different wafer layers. A third wafer having the memory device's remaining circuitry is bonded to the assembly using a process that interconnects the die of the third wafer to corresponding die on the other wafer layers.

Thus, it should be understood that by fabricating the die on each wafer using separate steps, and partitioning the functionality of the die on each layer, higher array efficiency may be achieved. In addition, the process to fabricate the circuitry on each layer may be independently optimized from the fabrication processes used to fabricate the other layers. This may lead to better performance and/or circuitry density.

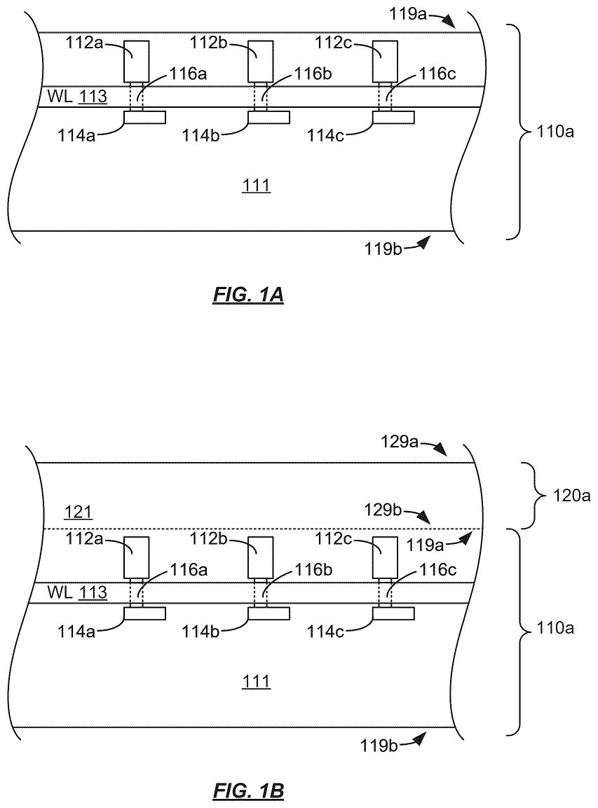

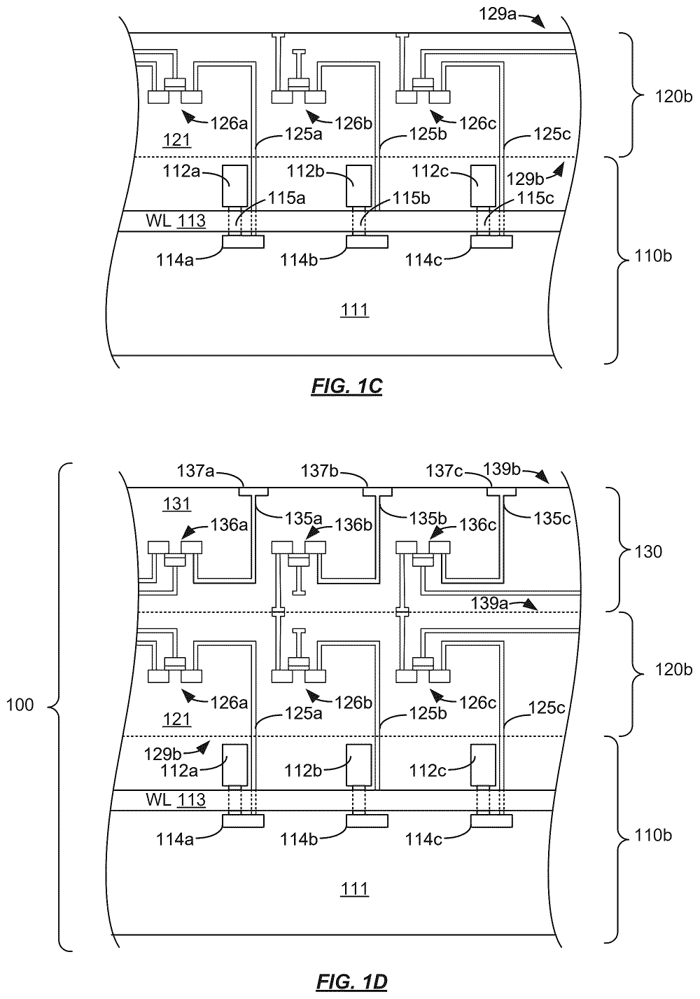

FIGS. 1A-1D are diagrams illustrating a first example layering of a memory device assembly. FIG. 1A illustrates a notional cross-section diagram of a first die layer. In FIG. 1, first die layer 110a comprises substrate 111, memory cell capacitors 112a-112c, wordlines 113, bitlines 114a-114c, and memory cell access transistors 116a-116c. First die layer 110a is also illustrated as having an active circuitry side 119a and a substrate side 119b. In an embodiment, memory cell access transistors 116a-116c may be, or comprise, gate all around (GAA) transistor structures. Thus, in an embodiment, one or more (or all) of memory cell capacitors 112a-112c, wordlines 113, bitlines 114a-114c, and/or memory cell access transistors 116a-116c may be disposed above the semiconductor (e.g., silicon) surface of substrate 111.

FIG. 1B illustrates a notional cross-section diagram after a blank wafer has been bonded to the first die layer and thinned. Second die layer 120a has an active circuitry side 129a and a substrate side 129b. In FIG. 1B, substrate 121 of second die layer 120a has been bonded to the active circuitry side 119a of first die layer 110a and then thinned. The bonding of second die layer 120a to first die layer 110a is illustrated by the dotted line between first die layer 110a and substrate 121 of second die layer 120a along the active circuitry side 119a of first die layer 110a.

FIG. 1C illustrates a notional cross-section diagram after the assembly of the first die layer and the second die layer has been processed to fabricate circuitry in the second die layer. In FIG. 1C, second die layer 120b comprises substrate 121 and active circuitry 126a-126c. The processing of second die layer 120b also forms vias 125a-125c in substrate 121 and first die layer 110b that interconnect the active circuitry 126a-126c of second die layer 110b with at least wordlines 113 and bitlines 114a-114c. In an embodiment, active circuitry 126a-126c comprise sense amplifiers and wordline driver circuitry. In FIG. 1C, processed second die layer 120b has been processed to fabricate circuitry on the active circuitry side 129a of second die layer 120a that is not in contact with first die layer 110b. Substrate side 129b of second die layer 120b is in contact with active circuitry side 119a of first die layer 110b.

FIG. 1D illustrates a notional cross-section diagram of a complete layered-die memory device assembly. In FIG. 1D, layered die assembly 100 comprises first die layer 110b, second die layer 120b, and a third die layer 130. Third die layer 130 includes at least digital logic circuitry 136a-136c, vias 135a-135c, and connection contacts 137a-137c. Active circuitry side 139a of third die layer 130 has been bonded to the active circuitry side 129a of second die layer 120b and thinned.

Active circuitry side 139a of third die layer 130 is bonded to active circuitry side 129a of second die layer 120a in a manner (e.g., hybrid wafer bonding) that allows connection contacts on the active circuitry side 129a of second die layer 120b to be in communication with connection contacts on the active circuitry side 139a of third die layer 130. This allows digital logic circuitry 136a-136c to be in communication with the active circuitry 126a-126c (e.g., sense amplifiers and wordline drivers) of second die layer 120b. Third die layer 130 has also been processed to form vias 135a-135c that interconnect digital logic circuitry 136a-136c and/or active circuitry 126a-126c to connection contacts 137a-137c (e.g., bonding pads, solder bumps, etc.) that enable communication with, for example, a memory controller.

Digital logic circuitry 136a-136c may process, for example, commands, addresses, and data to/from a memory controller (not shown in FIGS. 1A-1D) to access, using the active circuitry 126a-126c of second die layer 120b, the wordlines 113, bitlines 114a-114c, and access transistors of the first die layer 110b, data stored using memory cell capacitors 112a-112c of the first die layer 110b. The accessed data may be communicated via connection contacts 137a-137c.

From the foregoing, it should be understood that, in an embodiment, layered die assembly 100 may be a dynamic random access memory device, comprising a first die layer 110b, a second die layer 120b, and a third die layer 130. First die layer 110b has a substrate side 119b and an active circuitry side 119a. The active circuitry side 119a of the first die layer 110b may have a plurality of arrays of memory cell access transistors 116a-116c and memory cell capacitors 112a-112c that occupy a majority area of the active circuitry side 119a of the first die layer 110b.

Second die layer 120b has a substrate side 129b and an active circuitry side 129a. Substrate side 129b of second die layer 120b is disposed in contact with active circuitry side 119a of first die layer 110b. Active circuitry side 129a of the second die layer 120b may have sense amplifiers and wordline drivers that are to be in communication with the plurality of arrays of memory cell access transistors 116a-116c and memory cell capacitors 112a-112c. The sense amplifiers and wordline drivers may occupy a majority area of the active circuitry side 129a of the second die layer 120b.

Third die layer has a substrate side 139b and an active circuitry side 139a. The active circuitry side 139a of the third die layer 130 is disposed in contact with the active circuitry side 129a of the second die layer 120b. The active circuitry side 139a of the third die layer 130 may have digital logic circuitry 136a-136c that is to be in communication with the sense amplifiers and the wordline drivers of the second die layer 120b. The digital logic circuitry 136a-136c may process access commands, addresses, and data.

First die layer 110b and second die layer 120b may comprise vias to connect sense amplifiers to bitlines 114a-114c of the plurality of arrays of memory cell access transistors 116a-116c and memory cell capacitors 112a-112c and to connect wordline drivers of active circuitry 126a-126c to wordlines 113 of the plurality of arrays of memory cell access transistors 116a-116c and memory cell capacitors 112a-112c.

The first die layer 110b may have a first thickness between its substrate side 119b and its active circuitry side 119a. The second die layer may have a second thickness between its substrate side 129b and its active circuitry side 129a. The third die layer 130 may have a third thickness between its substrate side 139b and its active circuitry side 139a. In an embodiment, the second thickness may be less than the first thickness. In an embodiment, the second thickness may be less than the third thickness.

In some embodiments, active circuitry side 129a of the second die layer 120b is hybrid bonded to the active circuitry side 139a of the third die layer 130. Assembly 100 may be fabricated using wafer sized bonding operations and processing and after fabrication is complete, individual layered die assemblies 100 are cut (a.k.a., diced) from the bonded wafers. Thus, in an embodiment, the substrate side 119b and the active circuitry side 119a of the first die layer 110b, the substrate side 129b and the active circuitry side 129a of the second die layer 120b, and the substrate side 139b and the active circuitry side 139a of the third die layer 130b may each have substantially the same non-thickness dimensions. In other words, as viewed from the top or the bottom of assembly 100, each of first die layer 110b, second die layer 120b, and third die layer 130 may appear to be substantially the same area with substantially the same rectangular dimensions.

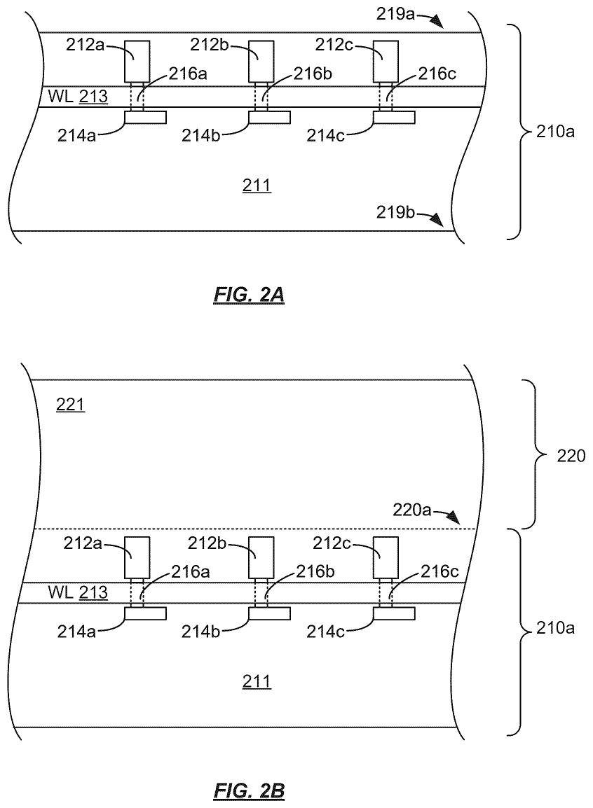

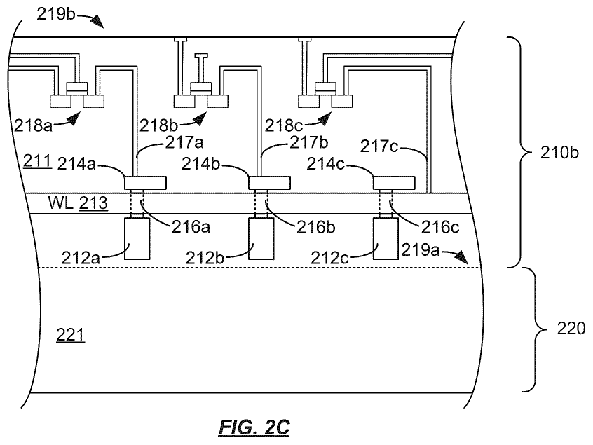

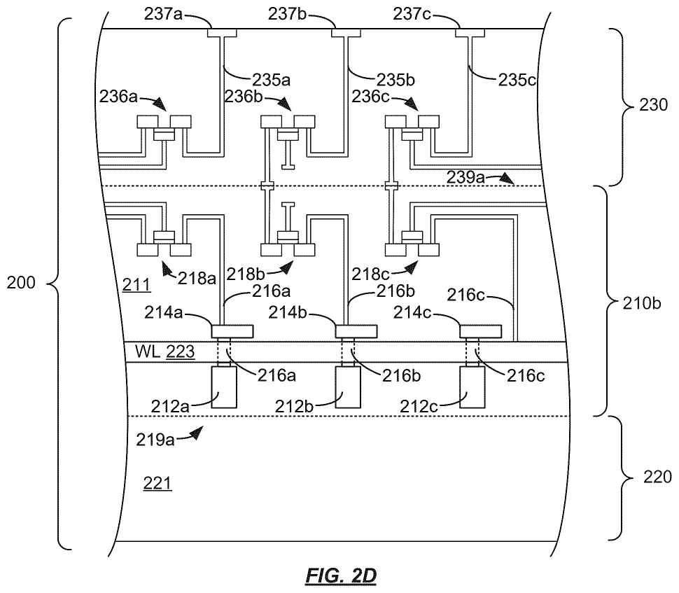

FIGS. 2A-2D are diagrams illustrating a second example layering of a memory device assembly. FIG. 2A illustrates a notional cross-section diagram of a first die layer. In FIG. 2, first die layer 210a comprises substrate 211, memory cell capacitors 212a-212c, wordlines 213, bitlines 214a-214c, and access transistors 216a-216c. First die layer 210a is also illustrated as having a memory array circuitry side 219a and an active circuitry side 219b. Memory cell capacitors 212a-212c, wordlines 213, bitlines 214a-214c, and access transistors 216a-216c are illustrated as being disposed and/or fabricated on the memory array circuitry side 219a of first die layer 210a. In an embodiment, access transistors 216a-216c may be, or comprise, gate all around (GAA) transistor structures. Thus, in an embodiment, one or more (or all) of memory cell capacitors 212a-212c, wordlines 213, bitlines 214a-214c, and access transistors 216a-216c may be disposed above the semiconductor (e.g., silicon) surface of substrate 211.

FIG. 2B illustrates a notional cross-section diagram after a carrier die wafer has been bonded to the first die layer. In FIG. 2B, substrate 221 of carrier die layer 220 has been bonded to the memory array circuitry side 219a of dual active sides die layer 210a. The bonding of carrier die contact side 220a of carrier die layer 220 to dual active sides die layer 210a is illustrated by the dotted line between dual active sides die layer 210a and carrier die contact side 220a (a surface of substrate 221) of carrier die layer 220 along the memory array circuitry side 219a of dual active sides die layer 210a.

FIG. 2C illustrates a notional cross-section diagram after the assembly of the first die layer and the second die layer has been processed to fabricate active circuitry on the “back” side the dual active sides die layer. Note that in FIGS. 2C-2D, the assembly of the first die layer and the second die layer is illustrated as flipped in the vertical direction relative to FIGS. 2A-2B. This is merely for illustration purposes to follow a convention where certain steps used in the fabrication of structures on a wafer often occurs on what is considered the “top” surface of the wafer. In FIG. 2C, dual active sides die layer 210b comprises substrate 211, memory cell capacitors 212a-212c, wordlines 213, bitlines 214a-214c, access transistors 216a-216c, and active circuitry 218a-218c. Memory cell capacitors 212a-212c, wordlines 213, bitlines 214a-214c, and access transistors 216a-216c are disposed and/or fabricated on memory array circuitry side 219a of dual active sides die layer 210b. Active circuitry 218a-218c is disposed and/or fabricated opposite memory array circuitry side 219a of dual active sides die layer 210b on active circuitry side 219b of dual active sides die layer 210b. The processing of dual active sides die layer 210b also forms vias 217a-217c in substrate 211 that interconnect active circuitry 218a-218c on active circuitry side 219b of dual active sides die layer 210b with at least wordlines 213 and bitlines 214a-214c of the memory array circuitry side 219a of dual active sides die layer 210b. In an embodiment, active circuitry 218a-218c comprise sense amplifiers and wordline driver circuitry. In FIG. 2C, processed dual active sides die layer 210b has been processed to fabricate active circuitry 218a-218c on the active circuitry side 229b of dual active sides die layer 210a that is not in contact with carrier die layer 220.

FIG. 2D illustrates a notional cross-section diagram of a complete layered-die memory device assembly. In FIG. 2D, layered die assembly 200 comprises dual active sides die layer 210b, carrier die layer 220, and logic circuitry die layer 230. Logic circuitry die layer 230 includes at least digital logic circuitry 236a-236c, vias 235a-235c, and connection contacts 237a-237c. Active circuitry side 239a of logic circuitry die layer 230 has been bonded to active circuitry side 219b of dual active sides die layer 210b and thinned.

Active circuitry side 239a of logic circuitry die layer 230 is bonded to active circuitry side 229b of dual active sides die layer 210a in a manner (e.g., hybrid wafer bonding) that allows connection contacts on the active circuitry side 229b of dual active sides die layer 220b to be in communication with connection contacts on the active circuitry side 239a of logic circuitry die layer 230. This allows digital logic circuitry 236a-236c to be in communication with the active circuitry 218a-218c (e.g., sense amplifiers and wordline drivers) of dual active sides die layer 210b. Logic circuitry die layer 230 has also been processed to form vias 235a-235c that interconnect digital logic circuitry 236a-236c and/or active circuitry 218a-218c to connection contacts 237a-237c (e.g., bonding pads, solder bumps, etc.) that enable communication with, for example, a memory controller.

Digital logic circuitry 236a-236c may process, for example, commands, addresses, and data to/from a memory controller (not shown in FIGS. 2A-2D) to access, using the active circuitry 218a-218c, the wordlines 213, bitlines 214a-214c, and access transistors of the dual active sides die layer 210b, data stored using memory cell capacitors 212a-212c of the dual active sides die layer 210b. The accessed data may be communicated via connection contacts 237a-237c.

From the foregoing, it should be understood that, in an embodiment, layered die assembly 200 may be a dynamic random access memory device, comprising a dual active side die layer 210b, a carrier die layer 220, and a logic circuitry die layer 230. Carrier die layer 220 has a carrier die contact side 220a. Dual active sides die layer 210b has a memory array circuitry side 219a and an active circuitry side 219b. Memory array circuitry side 219a of dual active sides die layer 210b is disposed in contact with carrier die contact side 220a of carrier die layer 220. Memory array circuitry side 219a of dual active sides die layer 210b may have a plurality of arrays of memory cell access transistors 215a-215c and memory cell capacitors 212a-212c occupying a majority area of memory array circuitry side 219a of the dual active sides die layer 210b. Active circuitry side 219b of the dual active sides die layer 210b may have sense amplifiers and wordline drivers that are to be in communication with plurality of arrays of memory cell access transistors 215a-215c and memory cell capacitors 212a-212c and are occupying a majority area of the active circuitry side 219b of the dual active sides die layer 210b. Logic circuitry die layer 230 has an active circuitry side 239a. Active circuitry side 239a of the logic circuitry die layer 230 is disposed in contact with the active circuitry side 219b of dual active sides die layer 210b. Active circuitry side 239a of logic circuitry die layer 230 may have digital logic circuitry 236a-236c that is to be in communication with sense amplifiers and wordline drivers of active circuitry side 219b. The digital logic circuitry 236a-236c may process access commands, addresses, and data.

In an embodiment, dual active sides die layer 210b may comprise vias to connect sense amplifiers of active circuitry side 219b to bitlines 214a-214c of memory array circuitry side 219a and to connect wordline drivers of active circuitry side 219b to wordlines 213 of memory array circuitry side 219a. Dual active sides die layer 210b has a first thickness between memory array circuitry side 219a and active circuitry side 219b. Logic circuitry die layer 230 has a second thickness between active circuitry side 239a and a substrate side of the logic circuitry die layer 230. In an embodiment, the second thickness is less than the first thickness. In another embodiment, the second thickness is greater than the first thickness.

In some embodiments, dual active sides die layer 210b is hybrid bonded to logic circuitry die layer 230. Assembly 200 may be fabricated using wafer sized bonding operations and processing and after fabrication is complete, individual layered die assemblies 200 are cut (a.k.a., diced) from the bonded wafers. Thus, in an embodiment, carrier die contact side 220a of carrier die layer 220, the memory array circuitry side 219a and active circuitry side 219b of the dual active sides die layer 210b, and the active circuitry side 239a of logic circuitry die layer 230 each have substantially the same non-thickness dimensions. In other words, as viewed from the top or the bottom of assembly 200, each of dual active sides die layer 210b, carried die layer 220, and logic circuitry die layer 230 may appear to be substantially the same area with substantially the same rectangular dimensions.

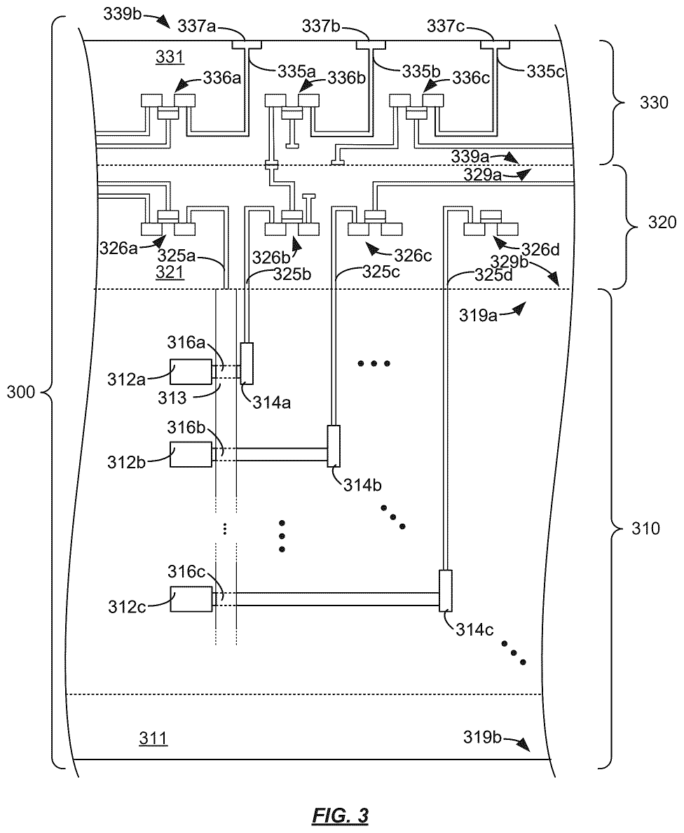

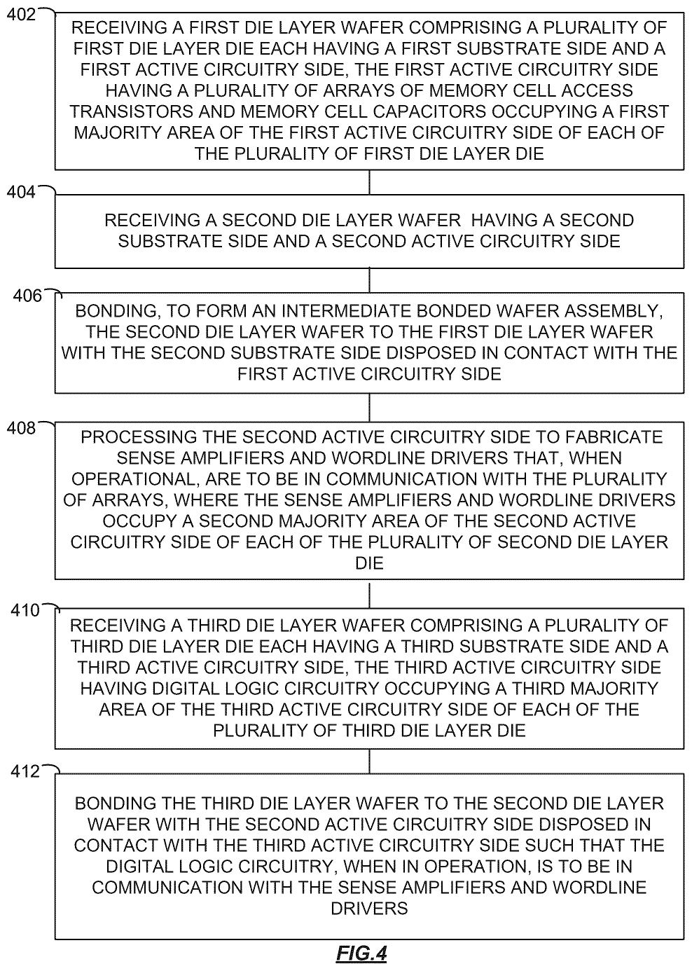

FIG. 3 illustrates a layered-die memory device assembly. FIG. 3 is a notional cross-section diagram of a completed layered-die assembly. Layered die assembly 300 comprises first die layer 310, second die layer 320, and a third die layer 330. In FIG. 3, first die layer 310 comprises substrate 311, memory cell capacitors 312a-312c, wordlines 313, bitlines 314a-314c, and memory cell access transistors 316a-316c. First die layer 310 is also illustrated as having an active circuitry side 319a and a substrate side 319b. In an embodiment, memory cell capacitors 312a-312c, wordlines 313, bitlines 314a-314c, and memory cell access transistors 316a-316c may be arranged and structured as 3D DRAM arrays. In an embodiment, memory cell capacitors 312a-312c, wordlines 313, bitlines 314a-314c, and memory cell access transistors 316a-316c may be arranged and/or disposed as a plurality of arrays of stacked layers. Thus, one or more (or all) of memory cell capacitors 312a-312c, wordlines 313, bitlines 314a-314c, and/or memory cell access transistors 316a-316c be disposed above the semiconductor (e.g., silicon) surface of substrate 311.

Substrate 321 of second die layer 320 has been bonded to the active circuitry side 319a of first die layer 310 and thinned. The bonding of second die layer 320 to first die layer 310 is illustrated by the dotted line between first die layer 310 and substrate 321 of second die layer 320 along the active circuitry side 319a of first die layer 310 and the substrate side 329b of second die layer 320. Second die layer 320 has been processed to fabricate active circuitry 326a-326d on the active circuitry side 329a of second die layer 320. Thus, second die layer 320 comprises substrate 321 and active circuitry 326a-326d. The processing of second die layer 320 also forms vias 325a-325d in substrate 321 and first die layer 310 that interconnect the active circuitry 326a-326d of second die layer 310 with at least wordlines 313 and bitlines 314a-314c. In an embodiment, active circuitry 326a-326d comprise sense amplifiers and wordline driver circuitry. Processed second die layer 320 has been processed to fabricate circuitry on the active circuitry side 329a of second die layer 320 that is not in contact with first die layer 310. Substrate side 329b of second die layer 320 is in contact with active circuitry side 319a of first die layer 310.

Third die layer 330 includes at least digital logic circuitry 336a-336c, vias 335a-335c, and connection contacts 337a-337c. Active circuitry side 339a of third die layer 330 has been bonded to the active circuitry side 329a of second die layer 320 and thinned.

Active circuitry side 339a of third die layer 330 is bonded to active circuitry side 329a of second die layer 320 in a manner (e.g., hybrid wafer bonding) that allows connection contacts on the active circuitry side 329a of second die layer 320 to be in communication with connection contacts on the active circuitry side 339a of third die layer 330. This allows digital logic circuitry 336a-336c to be in communication with the active circuitry 326a-326d (e.g., sense amplifiers and wordline drivers) of second die layer 320. Third die layer 330 has also been processed to form vias 335a-335c that interconnect digital logic circuitry 336a-336c and/or active circuitry 326a-326d to connection contacts 337a-337c (e.g., bonding pads, solder bumps, etc.) that enable communication with, for example, a memory controller.

Digital logic circuitry 336a-336c may process, for example, commands, addresses, and data to/from a memory controller (not shown in FIG. 3) to access, using the active circuitry 326a-326d of second die layer 320, the wordlines 313, bitlines 314a-314c, and access transistors of the first die layer 310, data stored using memory cell capacitors 312a-312c of the first die layer 310. The accessed data may be communicated via connection contacts 337a-337c.

From the foregoing, it should be understood that, in an embodiment, layered die assembly 300 may be a dynamic random access memory device, comprising a first die layer 310, a second die layer 320, and a third die layer 330. First die layer 310 has a substrate side 319b and an active circuitry side 319a. Active circuitry side 319a of first die layer 310 may have a plurality of arrays of memory cell access transistors 316a-316c and memory cell capacitors 312a-312c occupying a majority area of the active circuitry side 319a of first die layer 310. The plurality of arrays of memory cell access transistors 316a-316c and memory cell capacitors 312a-312c may comprise a plurality of stacked layers of memory cell access transistors 316a-316c and memory cell capacitors 312a-312c.

Second die layer 320 has a substrate side 329b and an active circuitry side 329a. Substrate side 329b of second die layer 320 is disposed in contact with the active circuitry side 319a of the first die layer 310. The active circuitry side 329a of the second die layer 320 may comprise sense amplifiers and wordline drivers that are to be in communication with the plurality of stacked layers of memory cell access transistors 316a-316c and memory cell capacitors 312a-312c of the plurality of arrays and may occupy a majority area of the active circuitry side 329a of the second die layer 320.

Third die layer 330 has a substrate side 339b and an active circuitry side 339a. The active circuitry side 339a of the third die layer 330 is disposed in contact with the active circuitry side 329a of the second die layer 320. The active circuitry side 339a of the third die layer 330 may have digital logic circuitry (e.g., 336a-336c) that is to be in communication with the sense amplifiers and the wordline drivers (e.g., 326a-326d), where the digital logic circuitry is to process access commands, addresses, and data.

Second die layer may also comprise vias 325a-325c to connect the sense amplifiers to bitlines of the plurality of stacked layers of the plurality of arrays and to connect the wordline drivers to wordlines of the plurality of stacked layers of the plurality of arrays. In an embodiment, first die layer 310 has a first thickness between its substrate side 319b and its active circuitry side 319a. Second die layer 320 has a second thickness between its substrate side 329b and its active circuitry side 329a. Third die layer 320 has a third thickness between its substrate side 339b and its active circuitry side 339a.18. In an embodiment, the third thickness may be less than the second thickness. In an embodiment, the second thickness may be less than the third thickness. In an embodiment, the substrate side 319b and the active circuitry side 319a of the first die layer 310, the substrate side 329b and the active circuitry side 329a of the second die layer 320, and the substrate side 339b and the active circuitry side 339a of the third die layer 330, each have substantially the same non-thickness dimensions.

FIG. 4 is a flowchart illustrating a first example method of assembling a layered-die memory device. One or more steps illustrated in FIG. 4 may be performed to, for example, produce assembly 100, assembly 200, assembly 300, and/or their components. A first die layer wafer comprising a plurality of first die layer die each having a first substrate side and a first active circuitry side is received, where the first active circuitry side has a plurality of arrays of memory cell access transistors and memory cell capacitors occupying a first majority area of the first active circuitry side of each of the plurality of first die layer die (402). For example, a first wafer comprising a plurality of first die layer 110a die that each have a plurality of arrays of memory cell access transistors 116a-166c and memory cell capacitors 112a-112c where the plurality of arrays of memory cell access transistors 116a-166c and memory cell capacitors 112a-112c occupy a majority of the active circuitry side 119a of each of the plurality of first die layer 110a die.

A second die layer wafer having a second substrate side and a second active circuitry side is received (404). For example, a second wafer may be received for later bonding to the first wafer. The second layer die wafer is bonded to the first die layer wafer with the second substrate side disposed in contact with the first active circuitry side (406). For example, the first wafer comprising the plurality of first die layer 110a die may be bonded with the second wafer such that substrate side 129b is in contact with active circuitry side 119a. The second active circuitry side is processed to fabricate sense amplifiers and wordline drivers that, when operation, are to be in communication with the plurality of arrays of memory cell access transistors and memory cell capacitors, where the sense amplifiers and wordline drivers occupy a second majority area of the second active circuitry side of each of the second die layer die (408). For example, the bonded wafer assembly comprising the first wafer and the second wafer may be processed to fabricate sense amplifiers and wordline drivers (e.g., active circuitry 126a-126c) on the active circuitry side 129a such that the sense amplifiers and wordline drivers occupy a majority of active circuitry side 129a of each of the plurality of second die layer 120b die on the second wafer.

A third die layer wafer comprising a plurality of third die layer die each having a third substrate side and a third active circuitry side is received, where the third active circuitry side has digital logic circuitry occupying a third majority area of the third active circuitry side of each of the plurality of third die layer die (410). For example, a third wafer comprising a plurality of third die layer 130 die that each have digital logic circuitry (e.g., digital logic circuitry 136a-136c) where the digital logic circuitry occupies a majority of the active circuitry side 139a of each of the plurality of third die layer 130 die.

The third die layer wafer is bonded to the second die layer wafer with the second active circuitry side disposed in contact with the third active circuitry side such that the digital logic circuitry, when in operation, is to be in communication with the sense amplifiers and wordline drivers (412). For example, the third wafer comprising the plurality of third die layer 130 die may be bonded with the second wafer comprising the plurality of second die layer 120b die and processed (e.g., to fabricate vias 135a-135c) such that digital logic circuitry (e.g., circuitry 136a-136b) of the die of the third wafer can be, when in operation, in communication with the sense amplifiers and wordline drivers of the die of the second wafer.

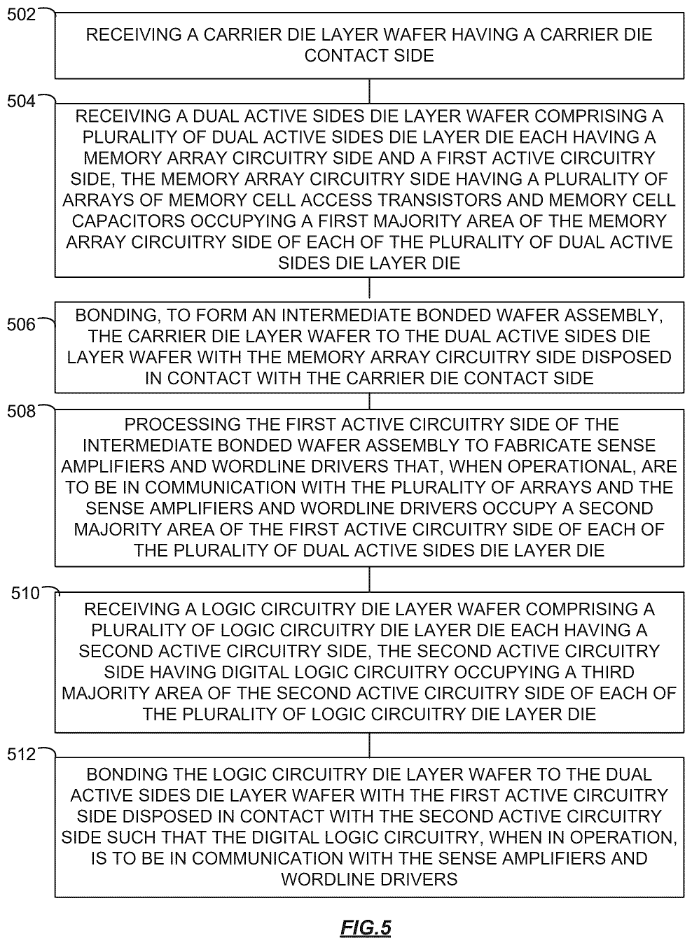

FIG. 5 is a flowchart illustrating a second example method of assembling a layered-die memory device. One or more steps illustrated in FIG. 5 may be performed to, for example, produce assembly 100, assembly 200, assembly 300, and/or their components. A carrier die layer wafer having a carrier die contact side is received (502). For example, a first wafer, that is blank or substantially blank (i.e., without, or substantially without, active circuitry) and having a contact side 220a that is to be bonded with another wafer may be received.

A dual active sides die layer wafer comprising a plurality of dual active sides die layer die each having a memory array circuitry sided and a first active circuitry side is received, where the memory array circuitry side has a plurality of arrays of memory cell access transistors and memory cell capacitors occupying a first majority area of the memory array circuitry side of each of the plurality of dual active sides die layer die (504). For example, a second wafer comprising a plurality of dual active sides die layer 210a die that each have a plurality of arrays of memory cell access transistors 216a-216c and memory cell capacitors 212a-212c where the plurality of arrays of memory cell access transistors 216a-216c and memory cell capacitors 212a-212c occupy a majority of the memory array circuitry side 219a of each of the plurality of dual active sides die layer 210a die on the second wafer.

The carrier die layer wafer is bonded to the dual active sides die layer wafer with the memory array circuitry side disposed in contact with the carrier die contact side to form an intermediate bonded wafer assembly (506). For example, the second wafer may be bonded to the first wafer such that the memory array circuitry side 219a of the dual active sides die layer die 210a of the second wafer are in contact with the first wafer. The first active circuitry side of the intermediate bonded wafer assembly is processed to fabricate sense amplifiers and wordline drivers that, when operation, are to be in communication with the plurality of arrays of memory cell access transistors and memory cell capacitors and the sense amplifiers and wordline drivers occupy a second majority area of the first active circuitry side of each of the plurality of dual active sides die layer die (508). For example, the bonded wafer assembly comprising the first wafer and the second wafer may be processed to fabricate sense amplifiers and wordline drivers (e.g., active circuitry 218a-218c) on the active circuitry side 219b such that the sense amplifiers and wordline drivers occupy a majority of active circuitry side 219b of each of the plurality of dual active sides die layer 210a die on the second wafer.

A logic circuitry die layer wafer comprising a plurality of logic circuitry die layer die each having a second active circuitry side is received, where the second active circuitry side has digital logic circuitry occupying a third majority area of the second active circuitry side of each of the plurality of logic circuitry die layer die (510). For example, a third wafer comprising a plurality of logic circuitry die layer 230 die that each have digital logic circuitry (e.g., digital logic circuitry 236a-236c) where the digital logic circuitry occupies a majority of the active circuitry side 239a of each of the plurality of logic circuitry die layer 330 die.

The logic circuitry die layer wafer is bonded to the dual active sides die layer wafer with the first active circuitry side disposed in contact with the second active circuitry side such that the digital logic circuitry, when in operation, is to be in communication with the sense amplifiers and wordline drivers (512). For example, the third wafer comprising the plurality of logic circuitry die layer 230 die may be bonded with the second wafer comprising the plurality of second die layer 220b die and processed (e.g., to fabricate vias 235a-235c) such that digital logic circuitry (e.g., circuitry 236a-236b) of the die of the third wafer can be, when in operation, in communication with the sense amplifiers and wordline drivers of the die of the second wafer.

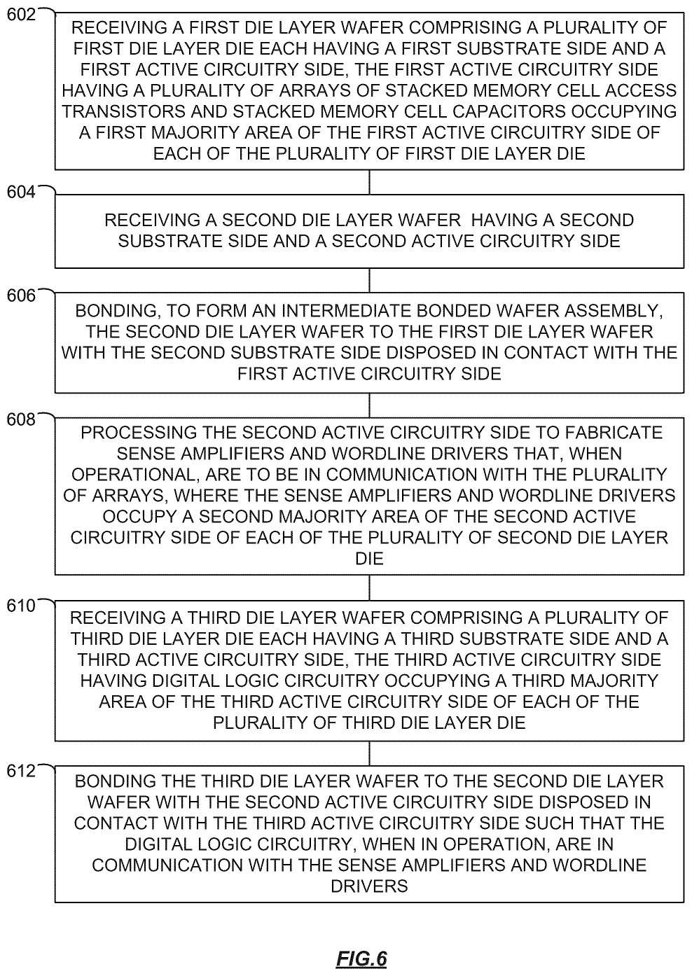

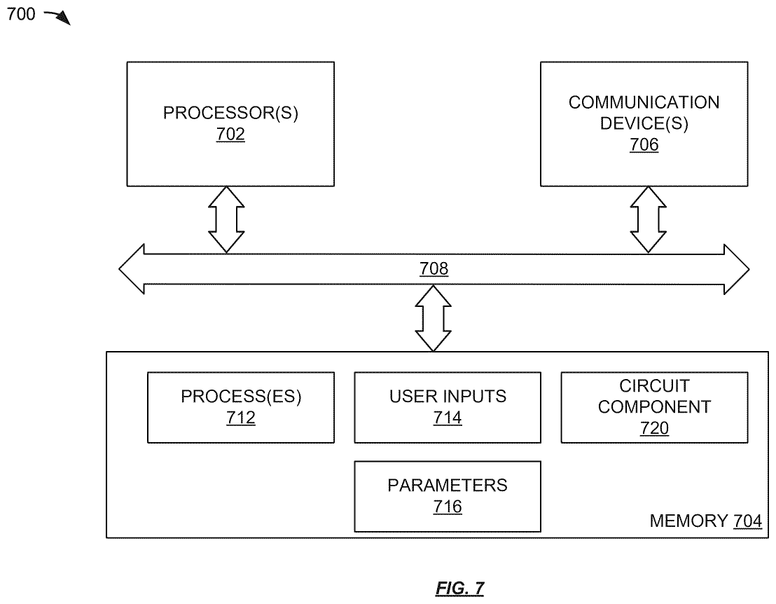

FIG. 6 is a flowchart illustrating a first example method of assembling a layered-die memory device. One or more steps illustrated in FIG. 6 may be performed to, for example, produce assembly 100, assembly 200, assembly 300, and/or their components. A first die layer wafer comprising a plurality of first die layer die each having a first substrate side and a first active circuitry side is received, where the first active circuitry side has a plurality of arrays of stacked memory cell access transistors and stacked memory cell capacitors occupying a first majority area of the first active circuitry side of each of the plurality of first die layer die (602). For example, a first wafer comprising a plurality of first die layer 310a die that each have a plurality of arrays of stacked memory cell access transistors 316a-366c and stacked memory cell capacitors 312a-312c where the plurality of arrays of stacked memory cell access transistors 316a-366c and stacked memory cell capacitors 312a-312c occupy a majority of the active circuitry side 319a of each of the plurality of first die layer 310a die.

A second die layer wafer having a second substrate side and a second active circuitry side is received (604). For example, a second wafer may be received for later bonding to the first wafer. The second layer die wafer is bonded to the first die layer wafer with the second substrate side disposed in contact with the first active circuitry side (606). For example, the first wafer comprising the plurality of first die layer 310 die may be bonded with the second wafer such that substrate side 329b is in contact with active circuitry side 319a. The second active circuitry side is processed to fabricate sense amplifiers and wordline drivers that, when operation, are to be in communication with the plurality of arrays of stacked memory cell access transistors and stacked memory cell capacitors, where the sense amplifiers and wordline drivers occupy a second majority area of the second active circuitry side of each of the second die layer die (608). For example, the bonded wafer assembly comprising the first wafer and the second wafer may be processed to fabricate sense amplifiers and wordline drivers (e.g., active circuitry 326a-326c) on the active circuitry side 329a such that the sense amplifiers and wordline drivers occupy a majority of active circuitry side 329a of each of the plurality of second die layer 320 die on the second wafer.

A third die layer wafer comprising a plurality of third die layer die each having a third substrate side and a third active circuitry side is received, where the third active circuitry side has digital logic circuitry occupying a third majority area of the third active circuitry side of each of the plurality of third die layer die (610). For example, a third wafer comprising a plurality of third die layer 330 die that each have digital logic circuitry (e.g., digital logic circuitry 336a-336c) where the digital logic circuitry occupies a majority of the active circuitry side 339a of each of the plurality of third die layer 330 die.

The third die layer wafer is bonded to the second die layer wafer with the second active circuitry side disposed in contact with the third active circuitry side such that the digital logic circuitry, when in operation, is to be in communication with the sense amplifiers and wordline drivers (612). For example, the third wafer comprising the plurality of third die layer 330 die may be bonded with the second wafer comprising the plurality of second die layer 320b die and processed (e.g., to fabricate vias 335a-335c) such that digital logic circuitry (e.g., circuitry 336a-336b) of the die of the third wafer can be, when in operation, in communication with the sense amplifiers and wordline drivers of the die of the second wafer.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of assembly 100, assembly 200, and/or assembly 300, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

FIG. 7 is a block diagram illustrating one embodiment of a processing system 700 for including, processing, or generating, a representation of a circuit component 720. Processing system 700 includes one or more processors 702, a memory 704, and one or more communications devices 706. Processors 702, memory 704, and communications devices 706 communicate using any suitable type, number, and/or configuration of wired and/or wireless connections 708.

Processors 702 execute instructions of one or more processes 712 stored in a memory 704 to process and/or generate circuit component 720 responsive to user inputs 714 and parameters 716. Processes 712 may be any suitable electronic design automation (EDA) tool or portion thereof used to design, simulate, analyze, and/or verify electronic circuitry and/or generate photomasks for electronic circuitry. Representation 720 includes data that describes all or portions of assembly 100, assembly 200, and/or assembly 300, and their components, as shown in the Figures.

Representation 720 may include one or more of behavioral, register transfer, logic component, transistor, and layout geometry-level descriptions. Moreover, representation 720 may be stored on storage media or communicated by carrier waves.

Data formats in which representation 720 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email

User inputs 714 may comprise input parameters from a keyboard, mouse, voice recognition interface, microphone and speakers, graphical display, touch screen, or other type of user interface device. This user interface may be distributed among multiple interface devices. Parameters 716 may include specifications and/or characteristics that are input to help define representation 720. For example, parameters 716 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 704 includes any suitable type, number, and/or configuration of non-transitory computer-readable storage media that stores processes 712, user inputs 714, parameters 716, and circuit component 720.

Communications devices 706 include any suitable type, number, and/or configuration of wired and/or wireless devices that transmit information from processing system 700 to another processing or storage system (not shown) and/or receive information from another processing or storage system (not shown). For example, communications devices 706 may transmit circuit component 720 to another system. Communications devices 706 may receive processes 712, user inputs 714, parameters 716, and/or circuit component 720 and cause processes 712, user inputs 714, parameters 716, and/or circuit component 720 to be stored in memory 704.

Implementations discussed herein include, but are not limited to, the following examples:

Example 1: A dynamic random access memory device, comprising: a first die layer having a first substrate side and a first active circuitry side, the first active circuitry side of the first die layer having a plurality of arrays of memory cell access transistors and memory cell capacitors occupying a first majority area of the first active circuitry side of the first die layer; a second die layer having a second substrate side and a second active circuitry side, the second substrate side of the second die layer disposed in contact with the first active circuitry side of the first die layer, the second active circuitry side of the second die layer having sense amplifiers and wordline drivers that are to be in communication with the plurality of arrays and are occupying a second majority area of the second active circuitry side of the second die layer; and a third die layer having a third substrate side and a third active circuitry side, the third active circuitry side of the third die layer disposed in contact with the second active circuitry side of the second die layer, the third active circuitry side of the third die layer having digital logic circuitry that is to be in communication with the sense amplifiers and the wordline drivers, the digital logic circuitry to process access commands, addresses, and data.

Example 2: The dynamic random access memory device of example 1, wherein the first die layer and the second die layer comprise vias to connect the sense amplifiers to bitlines of the plurality of arrays and to connect the wordline drivers to wordlines of the plurality of arrays.

Example 3: The dynamic random access memory device of example 1, wherein the first die layer has a first thickness between the first substrate side and the first active circuitry side, the second die layer has a second thickness between the second substrate side and the second active circuitry side, and the third die layer has a third thickness between the third substrate side and the third active circuitry side.

Example 4: The dynamic random access memory device of example 3, wherein the second thickness is less than the first thickness.

Example 5: The dynamic random access memory device of example 4, wherein the second thickness is less than the third thickness.

Example 6: The dynamic random access memory device of example 1, wherein the second active circuitry side is hybrid bonded to the third active circuitry side.

Example 7: The dynamic random access memory device of example 1, wherein the first substrate side and the first active circuitry side of the first die layer, the second substrate side and the second active circuitry side of the second die layer, and the third substrate side and the third active circuitry side each have substantially the same non-thickness dimensions.

Example 8: A dynamic random access memory device, comprising: a carrier die layer having a carrier die contact side; a dual active sides die layer having a memory array circuitry side and a first active circuitry side, the memory array circuitry side of the dual active sides die layer disposed in contact with the carrier die contact side of the carrier die layer, the memory array circuitry side of the dual active sides die layer having a plurality of arrays of memory cell access transistors and memory cell capacitors occupying a first majority area of memory array circuitry side of the dual active sides die layer, the first active circuitry side of the dual active sides die layer having sense amplifiers and wordline drivers that are to be in communication with the plurality of arrays and are occupying a second majority area of the first active circuitry side of the dual active sides die layer; and a logic circuitry die layer having a second active circuitry side, the second active circuitry side of the logic circuitry die layer disposed in contact with the first active circuitry side of the dual active sides die layer, the second active circuitry side of the logic circuitry die layer having digital logic circuitry that is to be in communication with the sense amplifiers and the wordline drivers, the digital logic circuitry to process access commands, addresses, and data.

Example 9: The dynamic random access memory device of example 8, wherein the dual active sides die layer comprises vias to connect the sense amplifiers to bitlines of the plurality of arrays and to connect the wordline drivers to wordlines of the plurality of arrays.

Example 10: The dynamic random access memory device of example 8, wherein the dual active sides die layer has a first thickness between the memory array circuitry side and the first active circuitry side, the logic circuitry die layer has a second thickness between the second active circuitry side and a substrate side of the logic circuitry die layer.

Example 11: The dynamic random access memory device of example 10, wherein the second thickness is less than the first thickness.

Example 12: The dynamic random access memory device of example 10, wherein the second thickness is greater than the first thickness.

Example 13: The dynamic random access memory device of example 8, wherein the first active circuitry side is hybrid bonded to the second active circuitry side.

Example 14: The dynamic random access memory device of example 8, wherein the carrier die contact side of the carrier die layer, the memory array circuitry side and the first active circuitry side of the dual active sides die layer, and the second active circuitry side of the logic circuitry die layer each have substantially the same non-thickness dimensions.

Example 15: A dynamic random access memory device, comprising: a first die layer having a first substrate side and a first active circuitry side, the first active circuitry side of the first die layer having a plurality of arrays of memory cell access transistors and memory cell capacitors occupying a first majority area of the first active circuitry side of the first die layer, the plurality of arrays of memory cell access transistors and memory cell capacitors comprising a plurality of stacked layers of memory cell access transistors and memory cell capacitors; a second die layer having a second substrate side and a second active circuitry side, the second substrate side of the second die layer disposed in contact with the first active circuitry side of the first die layer, the second active circuitry side of the second die layer having sense amplifiers and wordline drivers that are to be in communication with the plurality of stacked layers of memory cell access transistors and memory cell capacitors of the plurality of arrays and are occupying a second majority area of the second active circuitry side of the second die layer; and a third die layer having a third substrate side and a third active circuitry side, the third active circuitry side of the third die layer disposed in contact with the second active circuitry side of the second die layer, the third active circuitry side of the third die layer having digital logic circuitry that is to be in communication with the sense amplifiers and the wordline drivers, the digital logic circuitry to process access commands, addresses, and data.

Example 16: The dynamic random access memory device of example 15, wherein the second die layer comprises vias to connect the sense amplifiers to bitlines of the plurality of stacked layers of the plurality of arrays and to connect the wordline drivers to wordlines of the plurality of stacked layers of the plurality of arrays.

Example 17: The dynamic random access memory device of example 15, wherein the first die layer has a first thickness between the first substrate side and the first active circuitry side, the second die layer has a second thickness between the second substrate side and the second active circuitry side, and the third die layer has a third thickness between the third substrate side and the third active circuitry side.

Example 18: The dynamic random access memory device of example 17, wherein the third thickness is less than the second thickness.

Example 19: The dynamic random access memory device of example 18, wherein the second thickness is less than the third thickness.

Example 20: The dynamic random access memory device of example 15, wherein the first substrate side and the first active circuitry side of the first die layer, the second substrate side and the second active circuitry side of the second die layer, and the third substrate side and the third active circuitry side each have substantially the same non-thickness dimensions.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A dynamic random access memory device, comprising:
a first die layer having a first substrate side and a first active circuitry side, the first active circuitry side of the first die layer having a plurality of arrays of memory cell access transistors and memory cell capacitors occupying a first majority area of the first active circuitry side of the first die layer;
a second die layer having a second substrate side and a second active circuitry side, the second substrate side of the second die layer disposed in contact with the first active circuitry side of the first die layer, the second active circuitry side of the second die layer having sense amplifiers and wordline drivers that are to be in communication with the plurality of arrays and are occupying a second majority area of the second active circuitry side of the second die layer; and
a third die layer having a third substrate side and a third active circuitry side, the third active circuitry side of the third die layer disposed in contact with the second active circuitry side of the second die layer, the third active circuitry side of the third die layer having digital logic circuitry that is to be in communication with the sense amplifiers and the wordline drivers, the digital logic circuitry to process access commands, addresses, and data.

2. The dynamic random access memory device of claim 1, wherein the first die layer and the second die layer comprise vias to connect the sense amplifiers to bitlines of the plurality of arrays and to connect the wordline drivers to wordlines of the plurality of arrays.

3. The dynamic random access memory device of claim 1, wherein the first die layer has a first thickness between the first substrate side and the first active circuitry side, the second die layer has a second thickness between the second substrate side and the second active circuitry side, and the third die layer has a third thickness between the third substrate side and the third active circuitry side.

4. The dynamic random access memory device of claim 3, wherein the second thickness is less than the first thickness.

5. The dynamic random access memory device of claim 4, wherein the second thickness is less than the third thickness.

6. The dynamic random access memory device of claim 1, wherein the second active circuitry side is hybrid bonded to the third active circuitry side.

7. The dynamic random access memory device of claim 1, wherein the first substrate side and the first active circuitry side of the first die layer, the second substrate side and the second active circuitry side of the second die layer, and the third substrate side and the third active circuitry side each have substantially the same non-thickness dimensions.

8. A dynamic random access memory device, comprising:
a carrier die layer having a carrier die contact side;
a dual active sides die layer having a memory array circuitry side and a first active circuitry side, the memory array circuitry side of the dual active sides die layer disposed in contact with the carrier die contact side of the carrier die layer, the memory array circuitry side of the dual active sides die layer having a plurality of arrays of memory cell access transistors and memory cell capacitors occupying a first majority area of memory array circuitry side of the dual active sides die layer, the first active circuitry side of the dual active sides die layer having sense amplifiers and wordline drivers that are to be in communication with the plurality of arrays and are occupying a second majority area of the first active circuitry side of the dual active sides die layer; and
a logic circuitry die layer having a second active circuitry side, the second active circuitry side of the logic circuitry die layer disposed in contact with the first active circuitry side of the dual active sides die layer, the second active circuitry side of the logic circuitry die layer having digital logic circuitry that is to be in communication with the sense amplifiers and the wordline drivers, the digital logic circuitry to process access commands, addresses, and data.

9. The dynamic random access memory device of claim 8, wherein the dual active sides die layer comprises vias to connect the sense amplifiers to bitlines of the plurality of arrays and to connect the wordline drivers to wordlines of the plurality of arrays.

10. The dynamic random access memory device of claim 8, wherein the dual active sides die layer has a first thickness between the memory array circuitry side and the first active circuitry side, the logic circuitry die layer has a second thickness between the second active circuitry side and a substrate side of the logic circuitry die layer.

11. The dynamic random access memory device of claim 10, wherein the second thickness is less than the first thickness.

12. The dynamic random access memory device of claim 10, wherein the second thickness is greater than the first thickness.

13. The dynamic random access memory device of claim 8, wherein the first active circuitry side is hybrid bonded to the second active circuitry side.

14. The dynamic random access memory device of claim 8, wherein the carrier die contact side of the carrier die layer, the memory array circuitry side and the first active circuitry side of the dual active sides die layer, and the second active circuitry side of the logic circuitry die layer each have substantially the same non-thickness dimensions.

15. A dynamic random access memory device, comprising:
a first die layer having a first substrate side and a first active circuitry side, the first active circuitry side of the first die layer having a plurality of arrays of memory cell access transistors and memory cell capacitors occupying a first majority area of the first active circuitry side of the first die layer, the plurality of arrays of memory cell access transistors and memory cell capacitors comprising a plurality of stacked layers of memory cell access transistors and memory cell capacitors;
a second die layer having a second substrate side and a second active circuitry side, the second substrate side of the second die layer disposed in contact with the first active circuitry side of the first die layer, the second active circuitry side of the second die layer having sense amplifiers and wordline drivers that are to be in communication with the plurality of stacked layers of memory cell access transistors and memory cell capacitors of the plurality of arrays and are occupying a second majority area of the second active circuitry side of the second die layer; and
a third die layer having a third substrate side and a third active circuitry side, the third active circuitry side of the third die layer disposed in contact with the second active circuitry side of the second die layer, the third active circuitry side of the third die layer having digital logic circuitry that is to be in communication with the sense amplifiers and the wordline drivers, the digital logic circuitry to process access commands, addresses, and data.

16. The dynamic random access memory device of claim 15, wherein the second die layer comprises vias to connect the sense amplifiers to bitlines of the plurality of stacked layers of the plurality of arrays and to connect the wordline drivers to wordlines of the plurality of stacked layers of the plurality of arrays.

17. The dynamic random access memory device of claim 15, wherein the first die layer has a first thickness between the first substrate side and the first active circuitry side, the second die layer has a second thickness between the second substrate side and the second active circuitry side, and the third die layer has a third thickness between the third substrate side and the third active circuitry side.

18. The dynamic random access memory device of claim 17, wherein the third thickness is less than the second thickness.

19. The dynamic random access memory device of claim 18, wherein the second thickness is less than the third thickness.

20. The dynamic random access memory device of claim 15, wherein the first substrate side and the first active circuitry side of the first die layer, the second substrate side and the second active circuitry side of the second die layer, and the third substrate side and the third active circuitry side each have substantially the same non-thickness dimensions.
